(19) United States
(12) Patent Application Publication
(10) Pub. No.: US 2026/0323884 A1
(43) Pub. Date: Oct. 15, 2026

(54) HEAT DISSIPATION ASSEMBLY, SIGNAL TRANSMISSION DEVICE, AND ELECTRONIC APPARATUS

(71) Applicant: DONGGUAN LUXSHARE TECHNOLOGIES CO., LTD., Dongguan City (CN)

(72) Inventor: Kunlin Yao, Dongguan City (CN)

(73) Assignee: DONGGUAN LUXSHARE TECHNOLOGIES CO., LTD., Dongguan City (CN)

(21) Appl. No.: 19/374,307

(22) Filed: Oct. 30, 2025

(30) Foreign Application Priority Data
Apr. 9, 2025 (CN) 202510443989.1

(51) Int. Cl. H05K 7/20; G02B 6/42

(52) U.S. Cl. CPC H05K 7/20472; G02B 6/4269; H05K 7/20263; H05K 7/2049

(57) ABSTRACT

Provided are a heat dissipation assembly, a signal transmission device, and an electronic apparatus. The heat dissipation assembly includes a housing and two support columns. The housing includes a heat exchange chamber, and a liquid inlet and a liquid outlet, that are in communication with the heat exchange chamber. The heat exchange chamber is filled with a heat transfer fluid. A side surface of the housing includes a contact zone and a deformation zone. When the contact zone is in contact with a heat source device, the deformation zone generates elastic deformation. Two support columns are arranged at two sides of the housing, and an accommodation part is formed between the contact zone, the deformation zone, and the support columns.

### CROSS-REFERENCE TO RELATED APPLICATION

This application claims the benefit of Chinese Patent Application No. 202510443989.1, filed on Apr. 9, 2025, entitled “Heat Dissipation Assembly, Signal Transmission Device, and Electronic Apparatus”, which is incorporated herein by reference in its entirety.

### FIELD

The present disclosure relates to the technical field of heat dissipation, and particularly relates to a heat dissipation assembly, a signal transmission device, and an electronic apparatus.

### BACKGROUND

Electronic apparatuses can generate heat in long-term use. If the heat cannot be dissipated in time, it will directly affect operation of the electronic apparatuses. An instance is an optical module, which is applied to the fields such as data centers, the telecommunication industry or the Internet of Things, so as to achieve high-speed signal transmission between the electronic apparatuses. Too high temperature of the optical module will reduce performance of signal transmission and shorten its service life. How to improve heat dissipation efficiency of the electronic apparatuses has become a problem to be solved.

### SUMMARY

Embodiments of the present disclosure provide a heat dissipation assembly, a signal transmission device, and an electronic apparatus.

One aspect of embodiments of the present disclosure provides a heat dissipation assembly. The heat dissipation assembly includes: a housing and two support columns. The housing includes a heat exchange chamber, a liquid inlet and a liquid outlet. The liquid inlet and the liquid outlet are in communication with the heat exchange chamber, and the heat exchange chamber is filled with a heat transfer fluid. A side surface of the housing includes a contact zone and a deformation zone. When the contact zone is in contact with a heat source device, the deformation zone generates elastic deformation. The two support columns are arranged at two sides of the housing, and an accommodation part is formed between the contact zone, the deformation zone, and the support columns.

In some embodiments, the housing includes a housing body and a thermal conductive sheet. The housing body includes a recess, and the recess is located at the accommodation part. The thermal conductive sheet is arranged at the accommodation part, and forms the heat exchange chamber with the recess. The thermal conductive sheet includes the contact zone and the deformation zone, and the deformation zone is connected between the housing body and the contact zone.

In some embodiments, the deformation zone has a corrugated structure and surrounds the contact zone.

In some embodiments, the heat dissipation assembly further includes a heat exchange part located in the heat exchange chamber and arranged at the contact zone. The heat exchange part has a movement freedom degree in the heat exchange chamber, the heat exchange parts have a heat exchange gap, and the heat exchange gap is filled with the heat transfer fluid.

In some embodiments, the heat exchange part includes a base and a plurality of heat exchange bodies, the base abuts against the contact zone, and the plurality of heat exchange bodies are arranged at intervals and protrude from a side of the base away from the contact zone.

In some embodiments, the contact zone includes a plurality of contact zones, the heat exchange part includes a plurality of heat exchange parts in correspondence to the plurality of contact zones, the plurality of heat exchange parts are arranged at intervals in the heat exchange chamber, and the liquid outlet and the liquid inlet are located at two sides of the plurality of heat exchange parts.

Another aspect of embodiments of the present disclosure provides a signal transmission device. The signal transmission device includes: a first connection part, a second connection part, a mounting part, and a heat dissipation assembly. The second connection part includes a heat source device. The mounting part includes an accommodation cavity, and the accommodation cavity includes a window. The heat dissipation assembly includes a housing and two support columns. The housing includes a heat exchange chamber, a liquid inlet, and a liquid outlet, and the liquid inlet and the liquid outlet are in communication with the heat exchange chamber. The heat exchange chamber is filled with a heat transfer fluid, and the window faces the housing. One side surface of the housing includes a contact zone and a deformation zone. When the contact zone is in contact with the heat source device, the deformation zone generates elastic deformation. The two support columns are arranged at two sides of the housing, and an accommodation part is formed between the contact zone, the deformation zone, and the support columns. The support columns and the mounting part are fixedly connected to the first connection part. At least part of the mounting part is located in the accommodation part, and the second connection part is in communication connection with the first connection part. The contact zone moves away from the accommodation cavity, the deformation zone generates elastic deformation, and the contact zone is exposed in the accommodation cavity through the window.

In some embodiments, in a free state, the contact zone is recessed toward the accommodation cavity through the window.

In some embodiments, the accommodation cavity includes a plug-in opening, and the plug-in opening faces a lateral side of the window. The housing includes a housing body and a thermal conductive sheet. The housing body includes a recess, the recess is located at the accommodation part, and the thermal conductive sheet is arranged at the accommodation part and forms the heat exchange chamber with the recess. The thermal conductive sheet has a guide zone arranged opposite to the plug-in opening, and the guide zone is connected between the contact zone and the deformation zone. When the thermal conductive sheet is in a free state, a side of the guide zone connected to the contact zone is inclined in a direction away from the plug-in opening.

In some embodiments, the housing includes a housing body and a thermal conductive sheet, the housing body includes a recess, the recess is located at the accommodation part, and the thermal conductive sheet is arranged at the accommodation part and forms the heat exchange chamber with the recess. The heat dissipation assembly further includes a thermal conductive pad, one side surface of the thermal conductive pad is attached to the thermal conductive sheet, and the other side surface of the thermal conductive pad is exposed in the accommodation cavity through the window and forms the contact zone.

In some embodiments, the accommodation cavity includes a plug-in opening, and the plug-in opening faces a lateral side of the window. An edge of the thermal conductive pad includes an inclined guide surface, and one side of the inclined guide surface corresponding to the plug-in opening and away from the housing is inclined in a direction away from the plug-in opening.

In some embodiments, the first connection part includes a socket, and the socket is arranged in the accommodation cavity. The accommodation cavity includes a plug-in opening and the window, the contact zone is provided in correspondence to the window, and the plug-in opening faces a lateral side of the window. The heat source device is a plug, the plug is plugged into the accommodation cavity through the plug-in opening and is mated with the socket, and a side surface of the plug abuts against the contact zone.

Yet another aspect of embodiments of the present disclosure provides an electronic apparatus. The electronic apparatus includes: the signal transmission device according to the above aspect.

### BRIEF DESCRIPTION OF DRAWINGS

With reference to the following description of accompanying drawings on examples of the present disclosure, the above and other objectives, features and advantages of the present disclosure will become more apparent. In the drawings:

FIG. 1 is a schematic structural diagram of a signal transmission device of an embodiment of the present disclosure viewing from one side;

FIG. 2 is a schematic structural diagram of a signal transmission device of an embodiment of the present disclosure viewing from another side;

FIG. 3 is a schematic diagram of an exploded view of a signal transmission device of an embodiment of the present disclosure viewing from one side;

FIG. 4 is a schematic diagram of an exploded view of a signal transmission device of an embodiment of the present disclosure viewing from another side;

FIG. 5 is a schematic diagram of an exploded view of a signal transmission device of an embodiment of the present disclosure viewing from yet another side;

FIG. 6 is a cross sectional view of a heat dissipation apparatus of an embodiment of the present disclosure;

FIG. 7 is a cross sectional view of a signal transmission device of another embodiment of the present disclosure;

FIG. 8 is an enlarged partial view of a region B in FIG. 7;

FIG. 9 is a cross sectional view of a signal transmission device of another embodiment of the present disclosure; and

FIG. 10 is an enlarged partial view of a region C in FIG. 9.

### DETAILED DESCRIPTION OF THE EMBODIMENTS

The present disclosure will be described below based on examples, and the present disclosure is not limited to the examples. Some specific details will be described in detail in the following detailed description of the present disclosure. For those skilled in the art, the present disclosure can be fully understood without the description of these details. In order to avoid confusion of the essence of the present disclosure, well-known methods, processes, flows, elements and circuits are not described in detail.

In addition, it should be understood by those of ordinary skill in the art that the drawings provided herein are used for illustration and are not necessarily drawn to scale.

Unless expressly defined otherwise, “include”, “comprise” and other similar words in the entire application document should be interpreted as inclusive rather than exclusive or exhaustive, which mean “include but not limited to”.

In the description of the present disclosure, it should be understood that the terms such as “first” and “second” are merely used for description, and cannot be understood as indicating or implying relative importance. In addition, in the description of the present disclosure, “plurality” means two or more, unless otherwise specified.

Unless expressly specified and defined otherwise, the terms “mount”, “connect”, “connection” and “fix” are to be construed broadly. For instance, they can denote fixed connection, detachable connection or integral connection, denote direct connection or indirect connection through an intermediate medium, or denote communication between interiors of two elements or interaction between two elements, unless expressly defined otherwise. For those of ordinary skill in the art, specific meanings of the terms in the present disclosure may be understood according to specific circumstances.

For ease of description, space-related terms such as “inside”, “outside”, “under”, “below”, “lower portion”, “above” and “upper portion” are used herein for describing a relationship between one element or feature and another element or feature illustrated in the drawings. It is to be understood that the space-related terms may be intended to encompass different orientations of an apparatus in use or operation except orientations depicted in the drawings. For instance, if the apparatus in the drawings is reversed, an element described as being “below” or “under” another element or feature will be oriented as “above” another element or feature. Thus, the illustrative term “below” can include two orientations of above and below. The apparatus may be oriented in another manner (rotated by 90 degrees or at another orientation), and space-related descriptors used herein should be explained accordingly.

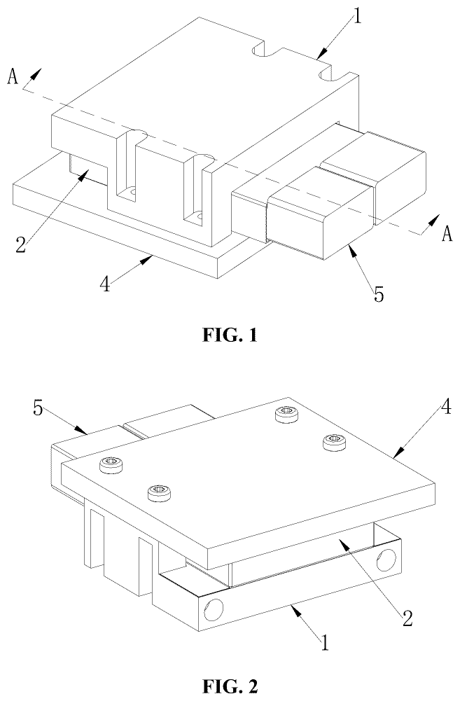

FIG. 1 and FIG. 2 are schematic structural diagrams of a signal transmission device of embodiments of the present disclosure.

In some embodiments, as shown in FIG. 1 to FIG. 2, the signal transmission device includes a heat dissipation apparatus, a first connection part 4, and a second connection part 5, and the first connection part 4, and the second connection part 5 are arranged to the heat dissipation apparatus. The heat dissipation apparatus includes a heat dissipation assembly 1 and a mounting part 2. The heat dissipation assembly 1 and the mounting part 2 are fixedly connected to the first connection part 4. The second connection part 5 is in communication connection with the first connection part 4. The heat dissipation assembly 1 includes a thermal conductive part 11.

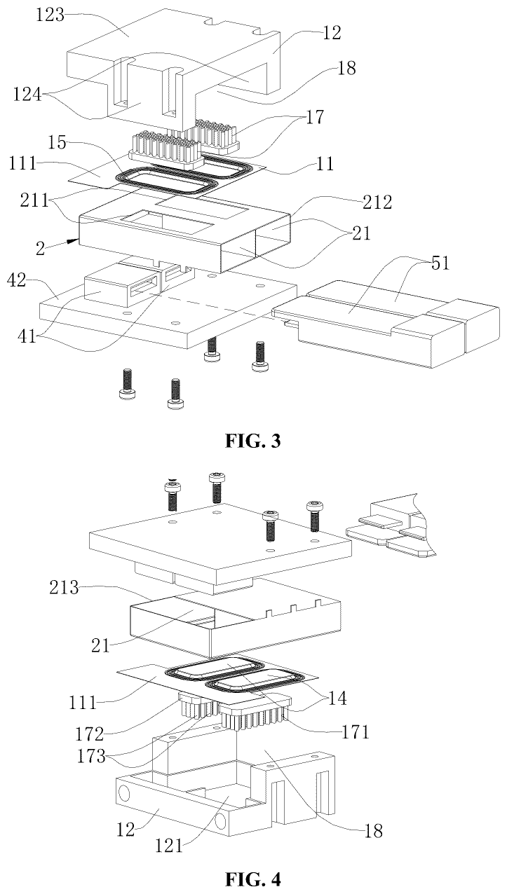

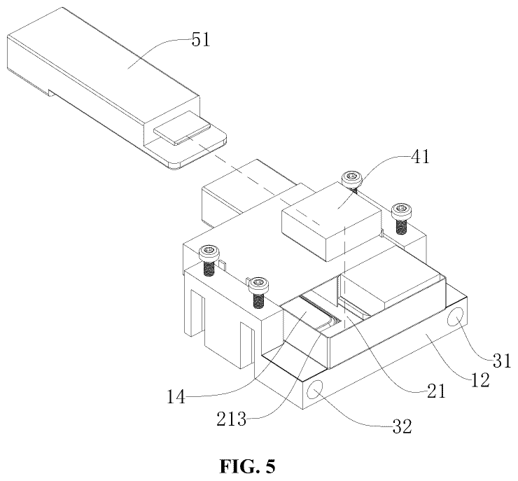

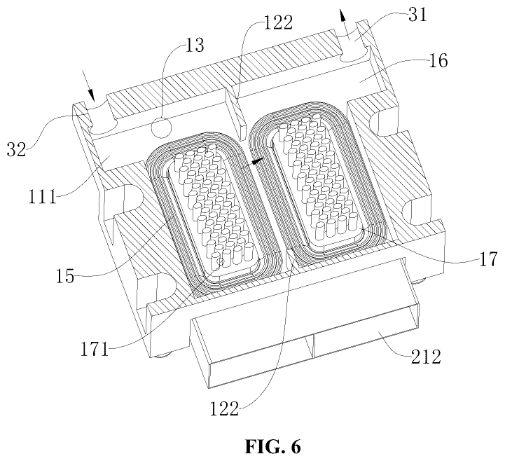

FIG. 3, FIG. 4 and FIG. 5 are exploded views of a signal transmission device of embodiments of the present disclosure. FIG. 6 is a cross sectional view of a heat dissipation apparatus of embodiments of the present disclosure.

In some embodiments, as shown in FIG. 3 to FIG. 5, the mounting part 2 includes one or more accommodation cavities 21. The second connection part 5 includes one or more heat source devices 51. The accommodation cavity 21 is configured to accommodate the heat source device 51.

In some embodiments, the mounting part 2 is a sheet metal part. The sheet metal part is subjected to bending, cutting or other processing processes to form the mounting part 2. Thus, the mounting part 2 is more convenient to process.

In some embodiments, as shown in FIG. 1 to FIG. 6, the heat dissipation assembly 1 includes a housing 12 and two support columns 124. The housing 12 includes a heat exchange chamber 16, and a liquid inlet 32 and a liquid outlet 31 that are in communication with the heat exchange chamber 16. The heat exchange chamber 16 is filled with a heat transfer fluid 13. One side surface of the housing 12 includes one or more contact zones 14 and one or more deformation zones 15. When the contact zone 14 contacts the heat source device 51, the deformation zone 15 generates elastic deformation. The two support columns 124 are arranged at two sides of the housing 12. An accommodation part 18 is formed between the two support columns 124, the contact zone 14, and the deformation zone 15.

For example, the housing 12 further includes a housing body 123. The two support columns 124 are located at two sides of the housing body 123 and extend toward a circuit board 42. The accommodation part 18 is located between the two support columns 124 and the housing body 123.

In the present embodiment, the deformation zone 15 enables the housing 12 to have an elastic deformation ability. When the contact zone 14 are pushed, the deformation zone 15 is deformed to cause displacement of the contact zone 14. The heat exchange chamber 16 is filled with the heat transfer fluid 13. A side of the contact zone 14 away from the heat exchange chamber 16 is exposed in the accommodation cavity 21. When the contact zone 14 moves in a direction away from the accommodation cavity 21, the deformation zone 15 generates elastic deformation, causing the contact zone 14 to abut against the heat source device 51. The two support columns 124 may be fixedly connected to the first connection part 4. The accommodation part 18 may be configured to accommodate the mounting part 2 and the second connection part 5.

In conclusion, according to the heat dissipation assembly 1 in the present embodiment, the housing 12 includes the liquid outlet 31 and the liquid inlet 32 that are in communication with the heat exchange chamber 16, such that the heat transfer fluid 13 is recycled. On one hand, when the heat source device 51 is in contact with the contact zone 14, elastic deformation generated by the deformation zone 15 ensures stable thermal conduction between the contact zone 14 and the heat source device 51. When the heat source device 51 is separated from the contact zone 14, the contact zone 14 is driven to get back to the initial position in time by the deformation zone 15. On the other hand, a height of the housing 12 is increased through the two support columns 124, which is conducive to assembly of the heat dissipation assembly 1 and a connection apparatus. In this way, the heat source device 51 conveniently abuts against the contact zone 14. In addition, the heat exchange chamber 16 is provided in the housing 12, such that a structure of the heat dissipation assembly 1 is simplified, and manufacturing cost is reduced.

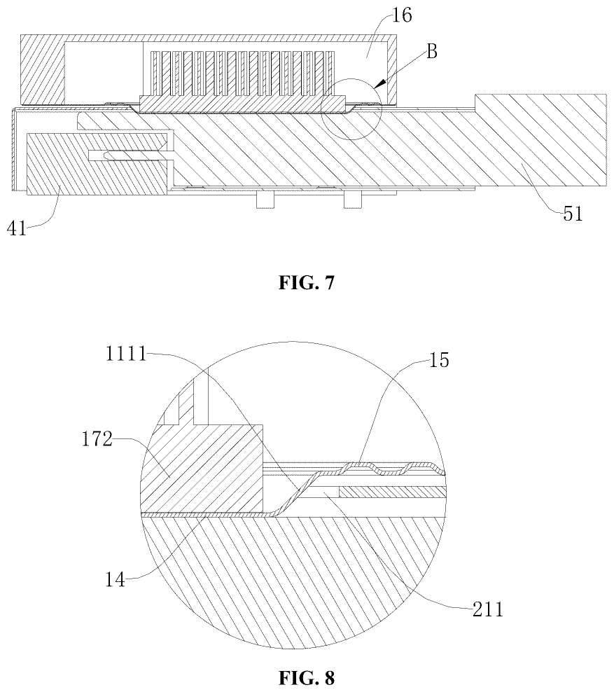

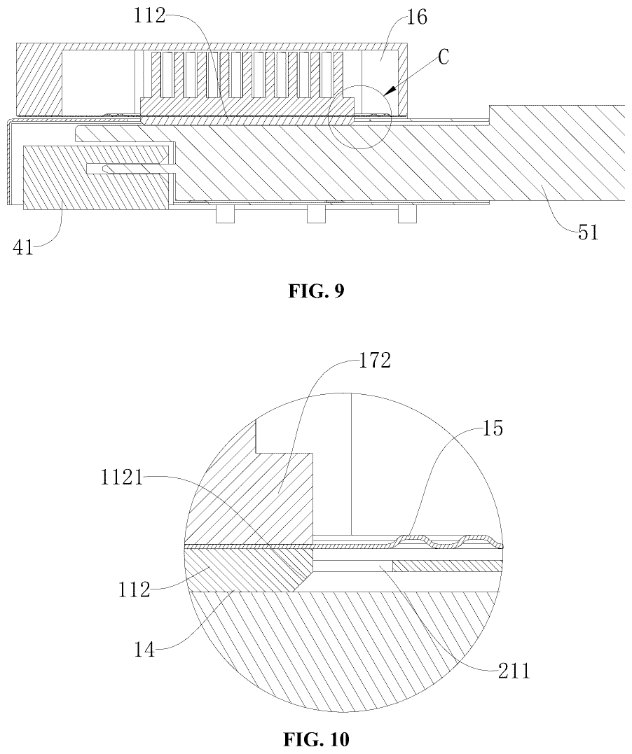

FIG. 7 and FIG. 9 are cross sectional views taken along line A-A in FIG. 1. FIG. 8 is an enlarged partial view of the region B in FIG. 7. FIG. 10 is an enlarged partial view of the region C in FIG. 9.

In some embodiments, as shown in FIG. 3 to FIG. 4 and FIG. 7 to FIG. 10, the housing 12 includes the housing body 123 and the thermal conductive part 11. The thermal conductive part 11 includes a thermal conductive sheet 111. The housing body 123 includes a recess 121. The recess 121 is located at the accommodation part 18. The thermal conductive sheet 111 is arranged at the accommodation part 18, and forms the heat exchange chamber 16 with the recess 121. The thermal conductive sheet 111 includes the contact zone 14 and the deformation zone 15. The deformation zone 15 is connected between the housing body 123 and the contact zone 14.

For example, one side of the thermal conductive sheet 111 seals the recess 121 to form the heat exchange chamber 16. The accommodation cavity 21 includes a window 211 facing the housing 12. The contact zone 14 is provided in correspondence to the window 211.

In some embodiments, the housing 12 has a connection surface. The connection surface includes the recess 121. An edge of the thermal conductive sheet 111 is welded to the connection surface, such that tightness and sealing of the heat exchange chamber 16 is ensured. The thermal conductive part 11 in the embodiment is in contact with both the heat source device 51 and the heat transfer fluid 13, such that thermal conduction efficiency is improved, and a heat dissipation effect of the heat dissipation assembly 1 is enhanced.

In some embodiments, as shown in FIG. 3 to FIG. 6, the heat dissipation assembly 1 further includes one or more heat exchange parts 17. The heat exchange part 17 is located in the heat exchange chamber 16 and arranged at the contact zone 14. The movement of the heat exchange part 17 in the heat exchange chamber 16 has a degree of freedom. The heat exchange part 17 has one or more heat exchange gaps 171. The heat exchange gap 171 is filled with the heat transfer fluid 13. For example, the heat exchange part 17 is located in the heat exchange chamber 16 and arranged on the thermal conductive sheet 111.

The heat exchange gap 171 increases a heat exchange area between the heat exchange part 17 and the heat transfer fluid 13. In this way, heat on the thermal conductive part 11 is conducted to the heat transfer fluid 13 more quickly. In addition, a size of the heat exchange part 17 is set. The thermal conductive sheet 111 drives the heat exchange part 17 to move through deformation of the thermal conductive sheet 111. Therefore, collision between the heat exchange part 17 and an inner wall of the heat exchange chamber 16 is avoided, such that a sufficient moving range of the contact zone 14 is ensured.

In some embodiments, materials of the thermal conductive part 11 and the heat exchange parts 17 may be aluminum alloy, copper, stainless steel, and the like. The heat transfer fluid 13 may be a water-based coolant (for instance, ethylene glycol or propylene glycol), an oil-based coolant (for instance, mineral oil or synthetic oil), or other media. Thus, thermal conductivity of the heat dissipation assembly 1 is improved.

In some embodiments, as shown in FIG. 4, the heat exchange part 17 includes a base 172 and a plurality of heat exchange bodies 173. The base 172 abuts against the contact zone 14. The plurality of heat exchange bodies 173 are arranged at intervals and protrude from a side of the bases 172 away from the contact zone 14. For example, the base 172 abuts against the thermal conductive sheet 111. The plurality of heat exchange bodies 173 are arranged at intervals and protrude from the side of the base 172 away from the thermal conductive sheet 111.

The base 172 is connected to the thermal conductive sheet 111 and conducts heat on the thermal conductive sheet 111 to the heat exchange bodies 173. Further, a contact area between the heat exchange part 17 and the thermal conductive sheet 111 is increased.

In some embodiments, the heat exchange bodies 173 may be sheet-like structures. The plurality of heat exchange bodies 173 are arranged at intervals to form fins. The heat exchange bodies 173 may be rod-shaped structures. The plurality of rod-shaped structures are arranged in parallel. An end of the rod-shaped structure or the fin away from the heat exchange body 173 is spaced apart from an inner wall of the accommodation cavity 21 by a predetermined distance, such that collision between the heat exchange body 173 and the inner wall of the accommodation cavity 21 is avoided.

In some embodiments, as shown in FIG. 5 to FIG. 6, the heat dissipation assembly includes a plurality of contact zones 14 and a plurality of heat exchange parts 17. The plurality of heat exchange parts 17 are provided in one-to-one correspondence to the plurality of contact zones 14. The plurality of heat exchange parts 17 are arranged at intervals in the heat exchange chamber 16. The liquid outlet 31 and the liquid inlet 32 are located at two sides of the plurality of heat exchange parts 17.

For example, the housing 12 includes the liquid outlet 31 and the liquid inlet 32. The liquid outlet 31 and the liquid inlet 32 are in communication with the heat exchange chamber 16. Thus, the heat transfer fluid 13 flows through each of the heat exchange parts 17, ensuring consistency of a heat dissipation speed in the contact zones 14.

In some embodiments, the plurality of accommodation cavities 21, the plurality of contact zones 14 and the plurality of heat exchange parts 17 are provided in a one-to-one correspondence. The plurality of accommodation cavities 21 are provided side by side. The accommodation cavities 21 are separated from each other by plates. The liquid outlet 31 and the liquid inlet 32 are located at a same side of the plurality of heat exchange parts 17. The plurality of heat exchange parts 17 are located between the liquid outlet 31 and the liquid inlet 32. Thus, the plurality of heat exchange parts 17 share the same heat exchange chamber 16, such that the heat dissipation assembly 1 simultaneously provide heat dissipation for the plurality of heat source devices 51. In addition, each of the contact zones 14 may move independently, such that a size of the accommodation cavity 21 may be adjusted according to a size of the corresponding heat source device 51.

In some embodiments, as shown in FIG. 6, the inner wall of the accommodation cavity 21 includes a separation plate 122. The separation plate 122 is located between two heat exchange parts 17. When the heat transfer fluid 13 flows in the heat exchange chamber 16, the heat transfer fluid may bypass the separation plate 122. In this way, the heat transfer fluid 13 fully contacts the heat exchange gaps 171 of each of the heat exchange parts 17 during flowing.

In some embodiments, as shown in FIG. 3 to FIG. 4, the deformation zone 15 is a corrugated structure. The corrugated structure surrounds the contact zone 14. Thus, the deformation zone 15 moves in a thickness direction of the thermal conductive sheet 111.

The contact zone 14 may be in contact with the heat source device 51 through the window 211. In addition, a zone around the contact zone 14 on the thermal conductive sheet 111 may be supported at edges of the window 211, thus ensuring shape stability of the thermal conductive sheet 111.

In some embodiments, a pressure value of the heat transfer fluid 13 in the heat exchange chamber 16 is set within a predetermined range (for instance, 50 kPa to 150 kPa), such that the heat transfer fluid 13 in the heat exchange chamber 16 has a sufficient flow velocity. Meanwhile, pressure of the heat transfer fluid 13 may generate downward pressure on the contact zone 14, such that the contact zone 14 is in stable contact with the heat source device 51, and the contact zone 14 can be reset in time after the heat source device 51 is taken out from the accommodation cavity 21.

In some embodiments, as shown in FIG. 1 to FIG. 10, the heat dissipation assembly 1 may be applied to a signal transmission device. The signal transmission device includes the mounting part 2, the first connection part 4, the second connection part 5, and the heat dissipation assembly 1. The heat dissipation assembly 1 includes the housing 12 and two support columns 124. The housing 12 includes the heat exchange chamber 16, and the liquid inlet 32 and the liquid outlet 31 that are in communication with the heat exchange chamber 16. The heat exchange chamber 16 is filled with the heat transfer fluid 13. The window 211 faces the housing 12. One side surface of the housing 12 includes the contact zone 14 and the deformation zone 15. When the contact zone 14 is in contact with the heat source device 51, the deformation zone 15 generate elastic deformation. The two support columns 124 are arranged at the two sides of the housing 12, and the accommodation part 18 is formed in the zone between the contact zone 14, the deformation zone 15, and the support columns. The support columns 124 and the mounting part 2 are fixedly connected to the first connection part 4. The mounting part 2 is at least partially located in the accommodation part 18. The second connection part 5 is in communication connection with the first connection part 4.

When the heat source device 51 is arranged in the accommodation cavity 21, the heat source device abuts against the contact zone 14. In this way, the heat source device 51 pushes the contact zone 14 to move in a direction away from the accommodation cavity 21, such that the deformation zone 15 generates elastic deformation, and the contact zone 14 is exposed in the accommodation cavity 21 through the window 211.

According to the signal transmission device in embodiments of the present disclosure, the mounting part 2 is fixedly connected to the first connection part 4, the heat source device 51 is accommodated in the accommodation cavity 21 of the mounting part 2, and the contact zone 14 is exposed in the accommodation cavity 21 through the window 211. Thus, on one hand, when the heat source device 51 is arranged in the accommodation cavity 21, the heat source device 51 is in direct contact with the contact zone 14, and the contact zones 14 is in stable contact with the heat source device 51 through elastic deformation generated by the deformation zone 15. When the heat source device 51 is taken out from the accommodation cavity 21, the contact zone 14 is reset to the initial position in time by the deformation zone 15. On the other hand, a height of the housing 12 is increased through the two support columns 124, which is conducive to assembly of the heat dissipation assembly 1 and the first connection part 4. In this way, the heat source device 5 conveniently abuts against the contact zone 14 and is in communication connection with the second connection part 5. In addition, the heat exchange chamber 16 is provided in the housing 12, such that a structure of the heat dissipation assembly 1 is simplified, and manufacturing cost is reduced.

In some embodiments, as shown in FIG. 7 to FIG. 8, the contact zone 14 is a part of the thermal conductive sheet 111. When the thermal conductive sheet 111 is in a free state, the contact zone 14 is recessed toward the accommodation cavity 21 through the window 211.

For example, the thermal conductive sheet 111 includes an intermediate sheet. The intermediate sheet is configured to form the contact zone 14. The deformation zone 15 is in a corrugated structure and surrounds the intermediate sheet. When the contact zone 14 is pushed by the heat source device 51, the corrugated structure contracts and deforms, and thus the corrugated structure drives the contact zone 14 to move in a direction away from the accommodation cavity 21. When the deformation zone 15 is in a free state, the deformation zone 15 is subjected to the downward pressure of the heat transfer fluid 13 and is supported at edges of the window 211.

In some embodiments, as shown in FIG. 5 to FIG. 8, the accommodation cavity 21 includes a plug-in opening 212. The plug-in opening 212 faces a lateral side of the window 211. For example, the window 211 is formed on a top surface of the accommodation cavity 21, and the plug-in opening 212 is formed on a lateral of the accommodation cavity 21. A normal line of a plane of the window 211 is perpendicular to a normal line of a plane of the plug-in opening 212. The thermal conductive sheet 111 has a guide zone 1111 arranged opposite to the plug-in opening 212. The guide zone 1111 is connected between the contact zone 14 and the deformation zone 15. When the thermal conductive sheet 111 is in a free state, a side of the guide zone 1111 connected to the contact zone 14 is inclined in a direction away from the plug-in opening 212. In some embodiments, the guide zone 1111 is annular. Inner edge of the guide zone 1111 is connected to the contact zone 14 and outer edge of the guide zone is connected to the deformation zone 15.

The guide zone 1111 plays a guiding role. When the heat source device 51 is inserted into the accommodation cavity 21 through the plug-in opening 212, an end of the heat source device 51 is in contact with the guide zone 1111, and thus the contact zone 14 is pushed to rise gradually until the contact zone 14 abuts against a side surface of the heat source device 51. Thus, friction between the heat source device 51 and the thermal conductive sheet 111 is reduced, and the thermal conductive sheet 111 and the heat source device 51 are prevented from being scratched in a process of repeated inserting and removal of the heat source device 51.

In some embodiments, as shown in FIG. 9 to FIG. 10, the heat dissipation assembly 1 further includes a thermal conductive pad 112. One side surface of the thermal conductive pad 112 is attached to the thermal conductive sheet 111. The other side surface of the thermal conductive pad is exposed in the accommodation cavity 21 through the window 211 and forms the contact zone 14.

In some embodiments, when the deformation zone 15 is in a free state, the intermediate sheet of the thermal conductive sheet 111 and the edge of the thermal conductive sheet 111 are located at a same plane. The thermal conductive pad 112 is attached to the intermediate sheet, such that the thermal conductive pad 112 enters the accommodation cavity 21 and abuts against the heat source device 51.

In some embodiments, as shown in FIG. 3 and FIG. 9 to FIG. 10, the accommodation cavity 21 includes the plug-in opening 212. The plug-in opening 212 faces a lateral side of the window 211. An edge of the thermal conductive pad 112 includes an inclined guide surface 1121. At least part of the inclined guide surface 1121 corresponds to the plug-in opening 212. One side of the inclined guide surface 1121 away from the housing 12 is inclined in a direction away from the plug-in opening 212.

The inclined guide surface 1121 plays a guiding role. When the heat source device 51 is inserted into the accommodation cavity 21 through the plug-in opening 212, the end of the heat source device 51 is in contact with the inclined guide surface 1121, and pushes the thermal conductive pad 112 to rise gradually until the thermal conductive pad 112 abuts against the side surface of the heat source device 51. Thus, friction between the heat source device 51 and the thermal conductive pad 112 is reduced, and the heat source device 51 is prevented from being scratched in a process of being repeated inserting and removal of the heat source device 51.

In some embodiments, as shown in FIG. 1 to FIG. 5, the first connection part 4 includes a socket 41. The socket 41 is arranged in the accommodation cavity 21. The accommodation cavity 21 includes the plug-in opening 212 and the window 211. The contact zone 14 is provided in correspondence to the window 211. The plug-in opening 212 faces the lateral side of the window 211. For example, the heat source device 51 is a plug. The plug is plugged into the accommodation cavity 21 through the plug-in opening 212 and is mated with the socket 41. Side surface of the plug abuts against the contact zone 14. Thus, detachable connection between the heat source device 51 and the socket 41 is implemented. In addition, after each plugging, the heat source device 51 abuts against the contact zone 14.

In some embodiments, the signal transmission device is configured to transmit optical signals or electrical signals. For example, signal transmission device transmits optical signals, the first connection part 4 and the second connection part 5 are in communication connection and form a high-speed connector. The optical transmission module may be applied to the fields such as data centers, the telecommunication industry, the Internet of Things, or transportation. With FIG. 3 as an instance, the signal transmission device includes two octal small form factor pluggable (OSFP) optical modules.

In some embodiments, as shown in FIG. 3, FIG. 4 and FIG. 5, the first connection part 4 includes the circuit board 42 and the socket 41 arranged on the circuit board 42. The accommodation cavity 21 includes clearance openings 213. An orientation of the clearance opening 213 is opposite to that of the window 211. That is, the clearance opening 213 faces the window 211. The socket 41 enters the accommodation cavity 21 through the clearance opening 213. The accommodation part 18 is formed in the zone between the two support columns 124 and the housing body 123. The accommodation part 18 is an accommodation recess. The two support columns 124 are connected to the circuit board 42 through screws, such that the accommodation recess is arranged on the circuit board 42 with its opening facing the circuit board. The mounting part 2 is located in the accommodation recess.

In some embodiments, the signal transmission device may be mounted in the following mode. Firstly, the mounting part 2 is fixed to the circuit board 42, and the socket 41 enters the accommodation cavity 21 through the clearance opening 213. Next, the heat exchange part 17 is welded to a side of the intermediate sheet. Next, the thermal conductive sheet 111 is welded to the housing body 123. As a result, the thermal conductive sheet 111 seals the recess 121, and the heat exchange part 17 is located inside the heat exchange chamber 16. Next, the two support columns 124 are fixedly connected to the circuit board 42 through screws, and the intermediate sheet enters the corresponding accommodation cavity 21 through the window 211 to form the contact zone 14. The mounting part 2 in the step is configured to bear the thermal conductive sheet 111, avoiding the thermal conductive sheet 111 from sagging downward. Finally, the heat source device 51 is inserted into the accommodation cavity 21 through the plug-in opening 212 and is mated with the socket 41.

In another embodiment, the signal transmission device is mounted in the following mode. Firstly, the mounting part 2 is fixed to the circuit board 42, and the socket 41 enter the accommodation cavity 21 through the clearance opening 213. The heat exchange part 17 is welded to one side of the intermediate sheet, and the thermal conductive pad 112 is welded to the other side of the intermediate sheet. Next, the thermal conductive sheet 111 is welded to the housing body 123 in such a manner that the thermal conductive sheet 111 seals the recess 121, and the heat exchange part 17 is located inside the heat exchange chamber 16. Next, the two support columns 124 are fixedly connected to the circuit board 42 through screws, and the thermal conductive pad 112 enter the corresponding accommodation cavity 21 through the window 211 to form the contact zone 14. Finally, the heat source device 51 is inserted into the accommodation cavity 21 through the plug-in opening 212 and is mated with the sockets 41.

In some embodiments, the signal transmission device may be applied to an electronic apparatus. The electronic apparatus includes, but is not limited to, a data center, a telecommunications apparatus, an Internet of Things apparatus, or a security apparatus.

In conclusion, according to the electronic apparatus in embodiments of the present disclosure, the mounting part 2 is fixedly connected to the first connection part 4, the heat source device 51 is accommodated in the accommodation cavity 21 of the mounting part 2, and the contact zone 14 is exposed in the accommodation cavity 21 through the window 211. Thus, on one hand, when the heat source device 51 is arranged in the accommodation cavity 21, the heat source devices 51 is in direct contact with the contact zone 14, and the contact zone 14 is in stable contact with the heat source device 51 through elastic deformation generated by the deformation zone 15. When the heat source device 51 is taken out from the accommodation cavity 21, the contact zone 14 is reset to the initial position in time by the deformation zone 15. On the other hand, a height of the housing 12 is increased through the two support columns 124, which is conducive to assembly of the heat dissipation assembly 1 and the first connection part 4. In this way, the heat source device 51 conveniently abuts against the contact zone 14 and is in communication connection with the second connection part 5. In addition, the heat exchange chamber 16 is provided in the housing 12, such that a structure of the heat dissipation assembly 1 is simplified, and manufacturing cost is reduced.

What are described above are merely exemplary examples of the present disclosure and are not intended to limit the present disclosure. Those skilled in art can make various modifications and changes to the present disclosure. Any modification, equivalent substitution, improvement, etc. within the spirit and principle of the present disclosure shall fall within the protection scope of the present disclosure.

What is claimed is:

1. A heat dissipation assembly, comprising: a housing and two support columns,
wherein the housing comprises a heat exchange chamber, a liquid inlet and a liquid outlet, the liquid inlet and the liquid outlet are in communication with the heat exchange chamber, and the heat exchange chamber is filled with a heat transfer fluid;
a side surface of the housing comprises a contact zone and a deformation zone, and when the contact zone is in contact with a heat source device, the deformation zone generates elastic deformation; and
the two support columns are arranged at two sides of the housing, and an accommodation part is formed between the contact zone, the deformation zone, and the support columns.

2. The heat dissipation assembly according to claim 1, wherein the housing comprises a housing body and a thermal conductive sheet;
the housing body comprises a recess, and the recess is located at the accommodation part; and
the thermal conductive sheet is arranged at the accommodation part, and forms the heat exchange chamber with the recess, and the thermal conductive sheet comprises the contact zone and the deformation zone, and the deformation zone is connected between the housing body and the contact zone.

3. The heat dissipation assembly according to claim 1, wherein the deformation zone has a corrugated structure and surrounds the contact zone.

4. The heat dissipation assembly according to claim 1, wherein the heat dissipation assembly further comprises a heat exchange part, and the heat exchange part is located in the heat exchange chamber and arranged at the contact zone; and
the heat exchange part has a movement freedom degree in the heat exchange chamber, the heat exchange parts have a heat exchange gap, and the heat exchange gap is filled with the heat transfer fluid.

5. The heat dissipation assembly according to claim 4, wherein the heat exchange part comprises a base and a plurality of heat exchange bodies, the base abuts against the contact zone, and the plurality of heat exchange bodies are arranged at intervals and protrude from a side of the base away from the contact zone.

6. The heat dissipation assembly according to claim 4, wherein the contact zone comprises a plurality of contact zones, the heat exchange part comprises a plurality of heat exchange parts in correspondence to the plurality of contact zones, the plurality of heat exchange parts are arranged at intervals in the heat exchange chamber, and the liquid outlet and the liquid inlet are located at two sides of the plurality of heat exchange parts.

7. A signal transmission device, comprising:
a first connection part;
a second connection part, comprising a heat source device;
a mounting part, comprises an accommodation cavity, wherein the accommodation cavity comprises a window; and
a heat dissipation assembly, comprising a housing and two support columns, wherein the housing comprises a heat exchange chamber, a liquid inlet, and a liquid outlet, the liquid inlet and the liquid outlet are in communication with the heat exchange chamber, the heat exchange chamber is filled with a heat transfer fluid, and the window faces the housing,
wherein one side surface of the housing comprises a contact zone and a deformation zone, and when the contact zone is in contact with the heat source device, the deformation zone generates elastic deformation, and the two support columns are arranged at two sides of the housing, and an accommodation part is formed between the contact zone, the deformation zone, and the support columns;
the support columns and the mounting part are fixedly connected to the first connection part, at least part of the mounting part is located in the accommodation part, and the second connection part is in communication connection with the first connection part; and
the contact zone moves away from the accommodation cavity, the deformation zone generates elastic deformation, and the contact zone is exposed in the accommodation cavity through the window.

8. The signal transmission device according to claim 7, wherein in a free state, the contact zone is recessed toward the accommodation cavity through the window.

9. The signal transmission device according to claim 7, wherein the accommodation cavity comprises a plug-in opening, and the plug-in opening faces a lateral side of the window;
the housing comprises a housing body and a thermal conductive sheet, the housing body comprises a recess, the recess is located at the accommodation part, and the thermal conductive sheet is arranged at the accommodation part and forms the heat exchange chamber with the recess;
the thermal conductive sheet has a guide zone arranged opposite to the plug-in opening, and the guide zone is connected between the contact zone and the deformation zone; and
when the thermal conductive sheet is in a free state, a side of the guide zone connected to the contact zone is inclined in a direction away from the plug-in opening.

10. The signal transmission device according to claim 7, wherein the housing comprises a housing body and a thermal conductive sheet, the housing body comprises a recess, the recess is located at the accommodation part, and the thermal conductive sheet is arranged at the accommodation part and forms the heat exchange chamber with the recess; and
the heat dissipation assembly further comprises a thermal conductive pad, one side surface of the thermal conductive pad is attached to the thermal conductive sheet, and the other side surface of the thermal conductive pad is exposed in the accommodation cavity through the window and forms the contact zone.

11. The signal transmission device according to claim 10, wherein the accommodation cavity comprises a plug-in opening, and the plug-in opening faces a lateral side of the window; and
an edge of the thermal conductive pad comprises an inclined guide surface, and one side of the inclined guide surface corresponding to the plug-in opening and away from the housing is inclined in a direction away from the plug-in opening.

12. The signal transmission device according to claim 10, wherein the first connection part comprises a socket arranged in the accommodation cavity;
the accommodation cavity comprises a plug-in opening and the window, the contact zone is provided in correspondence to the window, and the plug-in opening faces a lateral side of the window; and
the heat source device is a plug, the plug is plugged into the accommodation cavity through the plug-in opening and is mated with the socket, and a side surface of the plug abuts against the contact zone.

13. An electronic apparatus, comprising: a signal transmission device, wherein the signal transmission device comprises:
a first connection part;
a second connection part, comprising a heat source device;
a mounting part, comprises an accommodation cavity, wherein the accommodation cavity comprises a window; and
a heat dissipation assembly, comprising a housing and two support columns, wherein the housing comprises a heat exchange chamber, a liquid inlet, and a liquid outlet, the liquid inlet and the liquid outlet are in communication with the heat exchange chamber, the heat exchange chamber is filled with a heat transfer fluid, and the window faces the housing,
wherein one side surface of the housing comprises a contact zone and a deformation zone, and when the contact zone is in contact with the heat source device, the deformation zone generates elastic deformation, and the two support columns are arranged at two sides of the housing, and an accommodation part is formed between the contact zone, the deformation zone, and the support columns;
the support columns and the mounting part are fixedly connected to the first connection part, at least part of the mounting part is located in the accommodation part, and the second connection part is in communication connection with the first connection part; and
the contact zone moves away from the accommodation cavity, the deformation zone generates elastic deformation, and the contact zone is exposed in the accommodation cavity through the window.
